(19) United States
(12) Patent Application Publication
(10) Pub. No.: US 2023/0094606 A1
(43) Pub. Date: Mar. 30, 2023

(54) Creating Calibration Data for Completing Undersampled Measurement Data of an Object to be Examined by Means of a Magnetic Resonance System

(71) Applicant: Siemens Healthcare GmbH, Erlangen (DE)

(72) Inventors: Mario Zeller, Erlangen (DE); Adam Kettinger, Erlangen (DE)

(73) Assignee: Siemens Healthcare GmbH, Erlangen (DE)

(21) Appl. No.: 17/950,957

(22) Filed: Sep. 22, 2022

(30) Foreign Application Priority Data
Sep. 23, 2021 (DE) 102021210608.0

(51) Int. Cl. G01R 33/58; G01R 33/48; G01R 33/563

(52) U.S. Cl. CPC G01R 33/58; G01R 33/4818; G01R 33/56341

(57) ABSTRACT

Calibration data is generated for completing undersampled measurement data acquired via a magnetic resonance system. This includes recording N measurement data sets using an acquisition scheme, and undersampling the k-space with an acceleration factor R, with N being greater than or equal to R, and the N measurement data sets together scanning the k-space completely. Phase images are generated from the N recorded measurement data sets, at least one homogeneity value of the created phase images is determined, and a complete calibration data set is generated based upon the recorded measurement data sets, taking into account the at least one homogeneity value. Thus, it is possible to determine which measurement data sets are subject to undesired phase errors, the measurement data sets used for the creation of the calibration data sets can be selected optimally, and input of the detected phase errors into the calibration data sets can be avoided.

### CROSS-REFERENCE TO RELATED APPLICATIONS

The present application claims priority to and the benefit of Germany patent application no. DE 10 2021 210 608.0, filed on Sep. 23, 2021, the contents of which are incorporated herein by reference in its entirety.

### TECHNICAL FIELD

The disclosure relates to a method for creating calibration data for completing undersampled measurement data of an object to be examined by means of a magnetic resonance system.

### BACKGROUND

Magnetic resonance (MR) technology is a known technology with which images of the interior of an object to be examined can be created. In simple terms, the object to be examined is positioned in a magnetic resonance device in a comparatively strong, static, homogenous basic magnetic field, also referred to as a B0 field, with field strengths of 0.2 tesla to 7 tesla and more, so that its nuclear spins are oriented along the basic magnetic field. In order to trigger nuclear magnetic resonance, which can be measured as (echo) signals, radio-frequency (RF) excitation pulses are irradiated into the object to be examined, the triggered nuclear magnetic resonance is measured as so-called “k-space” data, and MR images are reconstructed on the basis thereof or spectroscopy data is determined. For spatial encoding of the measurement data, fast-switched magnetic gradient fields, called gradients for short, are superimposed on the basic magnetic field. A scheme used, which describes a time sequence of RF pulses to be irradiated and gradients to be switched, is referred to as a pulse sequence (scheme), or also as a sequence for short. The recorded measurement data is digitized and stored as complex numerical values in a k-space matrix. From the k-space matrix occupied by values, an associated MR image can be reconstructed, for example, by means of a multidimensional Fourier transformation.

Magnetic resonance imaging by means of a magnetic resonance system can serve to determine the presence and/or distribution of various tissues and/or a substance that is located in an object to be examined. The substance can be, for example, a potentially pathological tissue of the object to be examined, a contrast agent, a marker substance or a metabolic product.

### SUMMARY

Thus, information about existing tissues and substances can be obtained in a variety of ways from the recorded measurement data. A relatively simple source of information is, for example, image data reconstructed from the measurement data. However, there are also more complex methods which, for example, determine information about the object to be examined from image data reconstructed from a pixel time series of successively measured measurement data sets, i.e. measurement data sets which have been recorded by repetition of an acquisition scheme.

An example of methods that derive information about the object to be examined from a pixel time series of image data reconstructed from successively measured measurement data sets are methods of functional magnetic resonance imaging (fMRI). In functional magnetic resonance imaging, MR images of the brain of a subject or patient are recorded while being exposed to various stimuli. Information about the brain regions active in the respective stimuli is obtained from a comparison of a pixel time series of the recorded MR images with the time profile of the respective stimuli. fMRI methods include, for example, dynamic susceptibility contrast (DSC) methods, blood oxygenation level-dependent (BOLD) methods, as well as vascular space occupancy (VASO) methods as described, for example, in the article by Belliveau et al., “Functional Mapping of the Human Visual Vortex by Magnetic Resonance Imaging,” Science 254: p. 716-719 (1991), in the article by Ogawa et al., “Brain magnetic resonance imaging with contrast dependent on blood oxygenation,” Proc. Natl. Acad. Sci. 87: p. 9868-9872 (1990), or in the article by Lu et al., “Functional Magnetic Resonance Imaging Based on Changes in Vascular Space Occupancy” Magnetic Resonance in Medicine 50: p. 263-274 (2003).

For example, in the case of BOLD fMRI methods, a temporal series of, for example, T2*-sensitive image data sets is generally recorded by repeated acquisition of measurement data, in which temporary signal changes are determined by statistical analysis with comparison to a functional paradigm, for example, also spatial correlations in characteristic temporal signal profiles at rest states (resting state fMRI). In this case, for example, a 2D multi-layer gradient EPI sequence (EPI: echo planar imaging) with a “zigzag” Cartesian k-space trajectory (blipped EPI) or also with a spiral k-space trajectory (spiral EPI) can be used to record the measurement data. In this case, so-called “single-shot” methods are widely used, in which, after excitation, a complete set of measurement data, for example for a layer, is recorded, from which the image data for the pixel time series is reconstructed. However, these single-shot methods require longer repetition times TR the greater the resolution of the recorded measurement data is to be. Long repetition times TR can, however, lead to off-resonance artifacts, distortion, or blurring artifacts.

In principle, in order not to extend the repetition times TR despite higher resolution, or to accelerate the measurement in general, so-called parallel acquisition techniques (partially parallel acquisition (ppa) or Parallel Acquisition Technique (PAT)) can be used, such as, for example, GeneRalized Autocalibrating Partially Parallel Acquisition (GRAPPA) or Sensitivity Encoding (SENSE), in which only an amount of measurement data which is undersampled according to the Nyquist theorem in k-space is recorded with the aid of a plurality of RF coils. The “missing” measurement data is then supplemented in these methods on the basis of sensitivity data of the RF coils used and calibration data from the measured measurement data before the image data is reconstructed. Due to only some of the measurement data actually required for complete scanning being recorded (typically, for example, only half (=acceleration factor R=2) or a quarter (=acceleration factor R=4), or even only an eighth (=acceleration factor R=8) or less), the readout time required for reading the measurement data is reduced, and thus the repetition time is reduced. However, the sensitivity data of the RF coils and calibration data mentioned are required, necessitating additional measurements.

In the case of methods that determine information about the object to be examined from measurement data sets recorded through repeated measurement (i.e. a series of measurements) by means of an acquisition scheme, a specific measurement parameter of the acquisition scheme can be varied in order, for example, to analyze the effect of this measurement parameter on the object to be examined and, finally, to be able to draw diagnostic conclusions from the result. In this case, a measurement parameter is expediently varied in such a way that the contrast of a specific material type excited during the measurements, for example of a tissue type of the object to be examined or of a chemical substance that is significant for most or certain tissue types, such as, for example, water, is influenced as strongly as possible by the variation of the measurement parameter. This ensures that the effect of the measurement parameter on the object to be examined is particularly clearly visible.

A typical example of such series of measurements with variation of a measurement parameter strongly influencing the contrast are so-called diffusion-weighted imaging (DWI) methods. Diffusion is understood to mean the Brownian motion of molecules in a medium. In diffusion imaging, a plurality of images with different diffusion directions and weightings are generally recorded and combined with one another. The strength of the diffusion weighting is usually defined by the so-called “b-value”. The diffusion images with different diffusion directions and weightings, or the images combined therefrom, can then be used for diagnostic purposes. Thus, by means of suitable combinations of the recorded diffusion-weighted images, parameter maps with particular diagnostic significance can be created, such as, for example, maps which reproduce the Apparent Diffusion Coefficient (ADC) or Fractional Anisotropy (FA).

In diffusion-weighted imaging, additional gradients reflecting the diffusion direction and weighting are introduced into a pulse sequence to visualize or measure the diffusion properties of the tissue. These gradients lead to tissues with rapid diffusion (e.g. cerebrospinal fluid (CSF)) being subjected to a stronger signal loss than tissues with slow diffusion (e.g. the gray matter in the brain). The resulting diffusion contrast is becoming increasingly important clinically, and applications now go far beyond the classic early detection of ischemic stroke.

Diffusion imaging is often based on echo planar imaging (EPI) due to the short acquisition time of the EPI sequence per image and its robustness to motion. In the context of an EPI measurement, it may be possible for the recorded measurement data to have artifacts which impair the imaging of the object to be examined In detail, in the context of reading out the measurement data by means of EPI, a gradient train is typically applied which comprises a plurality of gradients of different polarity in a sequential sequence. Depending on the polarity, the gradient echoes created by the gradient train are sometimes referred to as “even” or “odd.” On account of the alternating polarity of the gradients of the gradient train, measurement data for different lines of the k-space are measured in the alternating direction. This means, for example, that measurement data for a first line are measured from left to right, and for a second line that is arranged in the k-space adjacent to the first line, from right to left.

In the case of EPI measurements, errors of the phase (i.e. phase errors) can occur, which cause artifacts. In particular, displacements of the phase of the measurement data for rows in k-space with different measuring directions can occur, as described above. This can occur, for example, due to time inaccuracies when applying the gradient pulses, during digitization in the context of recording the measurement data, and/or due to eddy current effects. Such an offset of the phase of the measurement data in adjacent rows of k-space can lead to so-called N/2 ghost artifacts. Such an N/2 ghost artifact can occur in the MR image as a “ghost” image of the object to be examined, and typically has a lower intensity than the actual image of the object to be examined and furthermore be displaced in a positive and/or negative direction with respect to the actual image of the object to be examined.

Methods for correcting such N/2 ghost artifacts are generally known. However, these are not satisfactorily effective when using parallel acquisition techniques, such as GRAPPA.

Thus, the object of the disclosure is to improve the quality of measurement data recorded using parallel acquisition techniques despite possible phase errors occurring.

The object is achieved by a method for creating calibration data for completing undersampled measurement data of an object to be examined by means of a magnetic resonance system, computer program, and an electronically readable data carrier as described in accordance with the embodiments herein, including the claims.

The disclosure is based on the finding that the signal evolution of the fully sampled measured echo signals for obtaining the calibration data can differ from the signal evolution of the undersampled measurement data for obtaining image data, which can lead to spatial distortions in the image data reconstructed from the measurement data completed using the calibration data.

A method according to the disclosure for creating calibration data for completing undersampled measurement data of an object to be examined by means of a magnetic resonance system comprises the steps of:
Recording of at least N measurement data sets using an acquisition scheme undersampling the k-space with an acceleration factor R, where N is greater than or equal to R, and where the N measurement data sets together at least fully sample the k-space,
Creating of phase images from the N recorded measurement data sets,
Determining at least one homogeneity value of the created phase images, and
Creating a complete calibration data set on the basis of the recorded measurement data sets, taking into account the at least one homogeneity value.

By taking into account homogeneity values according to the disclosure, it is possible to determine which measurement data sets are affected by undesired phase errors. For example, movements of the object to be examined, also pulse or respiratory movements, which take place during recording of measurement data, typically lead to changes in the phase distribution of the image data reconstructed from the measurement data. By taking into account the homogeneity values in the creation of calibration data sets, the measurement data sets used for the creation of the calibration data sets can be selected optimally, since measurement data corrupted e.g. by movements can be identified and excluded from use in the creation of calibration data sets. Input of the detected phase errors into the calibration data sets is thus avoided.

As a result, the image quality of the image data sets reconstructed from measurement data sets completed using the calibration data sets is improved. The measurement data sets to be recorded for the creation of calibration data sets according to the disclosure can be used simultaneously for imaging so that the time required for the measurement is not extended overall if the determined homogeneity values lie within a predetermined range. Even if certain homogeneity values are not within the predetermined range, the entire measurement does not have to be repeated, but instead only recordings of measurement data sets that are assigned to the homogeneity values are regarded as insufficient, as a result of which a time saving is still achieved.

A magnetic resonance system according to the disclosure comprises a magnet unit, a gradient unit, a radio-frequency unit, and a control device designed to carry out a method according to the disclosure with a homogeneity determination unit.

A computer program according to the disclosure implements a method according to the disclosure on a control device when the method is executed on the control device.

The computer program can also be in the form of a computer program product, which can be loaded directly into a memory of a control facility, with program code means, to carry out a method according to the disclosure when the computer program product is executed in the computing unit of the computer system.

An electronically readable data carrier (e.g. a non-transitory computer-readable medium) according to the disclosure comprises electronically readable control information stored thereon which comprises at least one computer program according to the disclosure and is designed in such a way that when the data carrier is used in a control device of a magnetic resonance system, it carries out a method according to the disclosure.

The advantages and embodiments specified in relation to the method also apply analogously to the magnetic resonance system, the computer program product, and the electronically readable data carrier.

### BRIEF DESCRIPTION OF THE DRAWINGS

Further advantages and details of the present disclosure will emerge from the exemplary embodiments described hereinafter and with reference to the diagrams. The examples given do not constitute a limitation of the disclosure. The diagrams show:

FIG. 1 illustrates a diagrammatic flow chart of an example method according to one or more embodiments of the disclosure;

FIG. 2 illustrates a diagrammatic view of an example acquisition scheme of recorded undersampled measurement data sets according to one or more embodiments of the disclosure; and

FIG. 3 illustrates a diagrammatic view of an example magnetic resonance system according to one or more embodiments of the disclosure.

### DETAILED DESCRIPTION OF THE DISCLOSURE

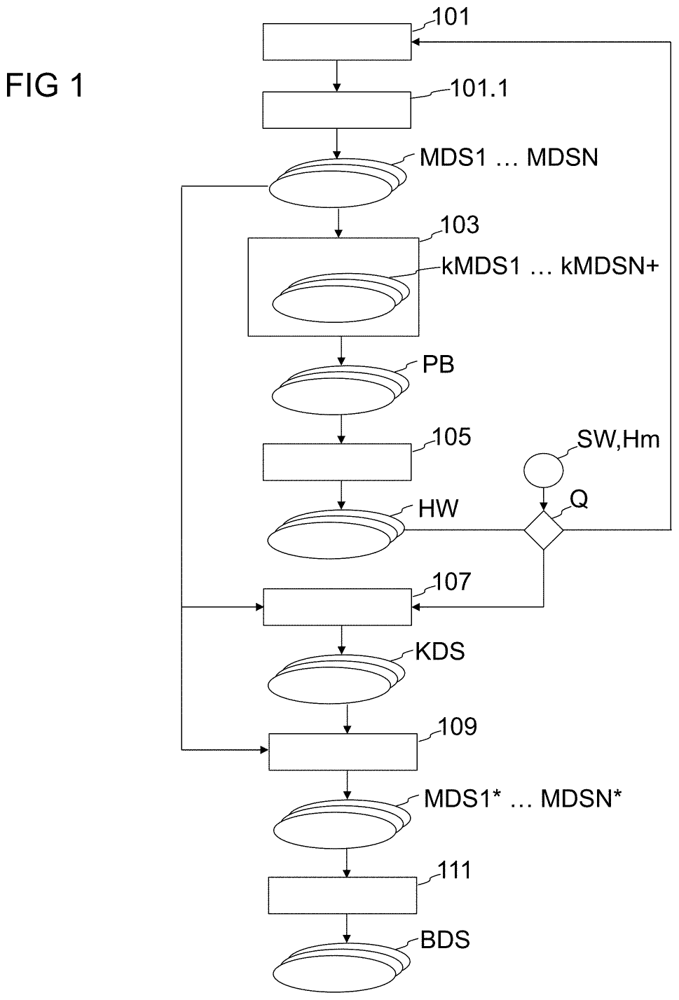

FIG. 1 is a diagrammatic flow chart of an example method according to the disclosure for creating calibration data for completing undersampled measurement data of an object to be examined by means of a magnetic resonance system.

At least N measurement data sets MDS1 . . . MDSN are recorded (block 101) using an acquisition scheme that undersamples the k-space and has an acceleration factor R, where N is greater than or equal to R, and where the N measurement data sets sample the k-space at least completely.

The recorded measurement data sets MDS1 . . . MDSN can be, for example, measurement data sets with diffusion value b=0 to be recorded repeatedly in the context of a diffusion measurement, or measurement data sets to be recorded repeatedly in the context of a functional magnetic resonance measurement. Furthermore, the recorded measurement data sets MDS1 . . . MDSN can be in the context of other reference data measurements to be carried out repeatedly, or measurement data sets to be recorded as dummy recordings, for example for dynamic field corrections or other dynamic reference measurements, such as for example, for t-GRAPPA (temporal GRAPPA).

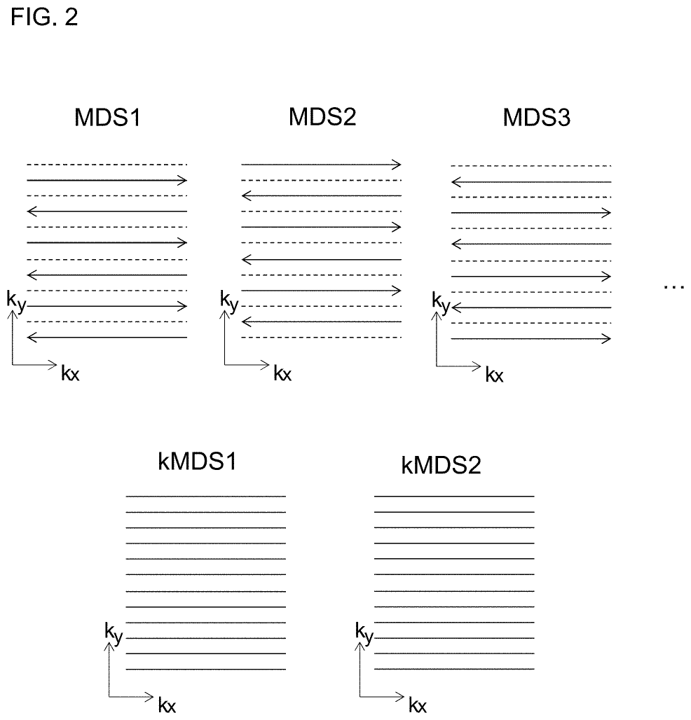

FIG. 2 shows diagrammatically example acquisition schemes of N=3 recorded undersampled measurement data sets MDS1, MDS, MDS3 above, as these can be used in the context of the method according to the disclosure.

In the example shown, the k-space for the measurement data sets MDS1, MDS2, MDS3 is sampled in k-space lines, from which measurement data are recorded, being represented as continuous lines (arrows) and omitted, and unrecorded k-space lines being represented as dashed lines. In the example shown, every second k-space line is sampled in each case in the phase encoding direction ky, and the measurement data sets MDS1, MDS2, MDS3 thus record the k-space segment-by-segment, and undersampled in each case with an acceleration factor R=2. The arrows indicate an exemplary direction in the readout direction kx, in which measurement data of the measurement data sets MDS1, MDS2, MDS3 are recorded, for example, by means of an EPI sequence.

The measurement data sets MDS1 and MDS2 can be combined to form a combined measurement data set kMDS1, which completely fills the k-space with measurement data as they complement one another to form a complete combined measurement data set kMDS1. Likewise, a combined measurement data set kMDS2 composed of the measurement data sets MDS2 and MDS3 completely covers the k-space. Thus, the N=3 measurement data sets MDS1, MDS2, MDS3 together sample the k-space even more than completely.

Phase images PB are created (block 103) from the N recorded measurement data sets MDS1 . . . MDSN, for example by a Fourier transformation of the measurement data sets MDS1 . . . MDSN into the image space. In the case of a Fourier transformation of undersampled recorded measurement data sets MDS1 . . . MDSN, folding artifacts are generally produced which, however, do not interfere with the further method according to the disclosure.

The recorded measurement data sets MDS1 . . . MDSN can also be corrected (block 101.1), for example if recorded by means of an EPI method, before the phase images are produced in each case by means of a phase correction known per se, for example for correcting Nyquist ghost artifacts, of the recorded measurement data sets MDS1 . . . MDSN. In the procedures described below, phase-corrected measurement data sets MDS1 . . . MDSN can be used in each case instead of the recorded measurement data sets MDS1 . . . MDSN if a phase correction has been carried out.

When creating the phase images PB, a phase image PB can be created from each of the N recorded measurement data sets MDS1 . . . MDSN.

It is also possible to combine a number M, with 2≤M≤R, of recorded measurement data sets MDS1 . . . MDSN to form at least one combined measurement data set kMDS1 . . . kMDSN+ (the number N+ of combined measurement data sets thus created can exceed N) and to determine a phase image PB of the at least one combined measurement data set kMDS1 . . . kMDSN+.

In this case, M recorded measurement data sets MDS1 . . . MDSN, from which a combined measurement data set kMDS1 is to be produced, can be selected in such a way that the combined measurement data set kMDS1 completely scans the k-space, and thus results in a combined complete measurement data set kMDS1.

Furthermore, it is possible to create a combined measurement data set kMDS1 . . . kMDSN+, which comprises at least two recorded measurement data sets MDS1 . . . MDSN averaged, which scan the same k-space positions. In other words, recorded measurement data sets MDS1 . . . MDSN can be combined to form a combined measurement data set kMDS1 . . . kMDSN+, even if these contain measurement data that scan the same k-space positions. Measurement data for k-space positions, which were thus recorded several times (as recorded in various of the combined measurement data sets MDS1 . . . MDSN), can be recorded averaged in the combined measurement data set kMDS1 . . . kMDSN+. In the example of the measurement data sets of FIG. 2, for example, the measurement data of the measurement data sets MDS1 and MDS3, as these scan the same k-space positions (here k-space lines), can be averaged, and recorded in a combined measurement data set kMDS1 . . . kMDSN+, which is composed of at least the measurement data sets MDS1 and MDS3. Such averaging of measured values in combined measurement data sets kMDS1 . . . kMDSN+ can already cause a smoothing of the phase in phase images PB produced in this way with averaging of combined measurement data sets kMDS1 . . . kMDSN+, which has a positive effect on a homogeneity value of the phase image.

At least one homogeneity value HW of the created phase images is determined (block 105).

The determination of a homogeneity value can be, for example, a calculation of absolute values of phase gradients, a determination of autocorrelation values of the phase images in at least one dimension, e.g. in all recorded dimensions, and/or a determination of Haralick's homogeneity index, HHI. In the article by Benner et al. “Diffusion Imaging with Prospective Motion Correction and Reacquisition,” MRM 66, p. 154 (2011), magnitude and phase information from DWI images is used to determine homogeneity values, on the basis of which it is decided which layers are to be measured again in order to avoid artifacts. In the article by Liang et al. “Prospective Motion Detection and Re-acquisition in Diffusion MRI using Phase image-based Method (PITA-MDD),” Proc. Intl. Soc. Mag. Reson. Med. 28 p. 0979 (2020), Haralick's homogeneity index is used as a homogeneity value to also identify layers which are to be measured again.

On the basis of the recorded measurement data sets MDS1 . . . MDSN, which may have been phase-corrected, and taking into account the at least one homogeneity value HW, a complete calibration data set KDS which completely fills the k-space is created (block 107).

Such consideration of homogeneity values HW can be carried out, for example, by various queries which identify, for example, measurement data sets MDS1 . . . MDSN or combined measurement data sets kMDS1 . . . kMDSN+ which are not used in the creation of the calibration data set.

Generated homogeneity values HW of the determined phase images PB can, for example, be compared with one another (query Q). If phase images have been created for all, possibly phase-corrected, measurement data sets MDS1 . . . MDSN and, if a deviation of a homogeneity value HW of a phase image PB determined from a first recorded measurement data set MDS1 from homogeneity values HW of other phase images PB determined from other recorded measurement data sets MDS2 MDSN is detected, the first recorded measurement data set MDS1 identified as deviating in this way can be excluded from use in the generation of the calibration data set KDS if the deviation exceeds a predetermined threshold value SW.

By comparing the homogeneity values HW of the phase images PB and identifying homogeneity values HW deviating above the threshold value, a similarity of the phase distribution in the phase images PB can be ensured, which measurement data sets MDS1 . . . MDSN are assigned (as they were created from these measurement data sets MDS1 . . . MDSN), which are used for the generation of calibration data set KDS.

Additionally or alternatively, generated homogeneity values HW of the determined phase images PB can be compared with a predetermined minimum homogeneity value Hm (query Q). If the homogeneity value HW of a phase image PB determined from a second recorded measurement data set MDS2 does not reach the minimum homogeneity value Hm, the second recorded measurement data set MDS2 thus identified as inadequate can be excluded from use in the creation of the calibration data set KDS.

Such a minimum homogeneity value Hm can ensure that the measurement data sets MDS1 . . . MDSN used for the creation of calibration data sets KDS have a minimum requirement and display homogeneity, and thus provide freedom from phase errors.

If phase images PB were created for combined measurement data sets kMDS1 . . . kMDSN+ and if, during the comparison, a deviation of a homogeneity value HW of a phase image PB determined from a first combined measurement data set kMDS1 from homogeneity values HW of other phase images PB determined from measurement data sets kMDS2 kMDSN+ combined from at least partially different recorded measurement data sets MDS1 . . . MDSN is determined, the first combined measurement data set kMDS1 identified as deviating in this way can be excluded from use in the creation of the calibration data set KDS if the deviation exceeds a predetermined threshold value SW.

Analogously to the case described above, in which a respective phase image PB was created for each measurement data set MDS1 . . . MDSN, a similarity of the phase distribution in the phase images PB can also be ensured here by comparing the homogeneity values HW of the phase images PB of the combined measurement data sets kMDS1 . . . kMDSN+ and identifying homogeneity values HW deviating above the threshold value, which measurement data sets MDS1 . . . MDSN are assigned (as they were produced from these measurement data sets MDS1 . . . MDSN) which are used for the creation of the calibration data set KDS.

In particular, if phase images PB were created for combined measurement data sets kMDS1 . . . kMDSN+, created homogeneity values HW of the determined phase images PB can additionally or alternatively be compared with a predetermined minimum homogeneity value Hm (query Q) and, if the homogeneity value HW of a phase image PB determined from a second combined measurement data set kMDS2 does not reach the minimum homogeneity value Hm, the second combined measurement data set kMDS2 identified as insufficient in this way is excluded from use in the creation of the calibration data set KDS.

Again, analogously to the case described above, in which a respective phase image PB was created for each measurement data set MDS1 . . . MDSN, it can be ensured by means of such a minimum homogeneity value Hm that the measurement data sets MDS1 . . . MDSN used for the creation of calibration data sets KDS have a minimum requirement and display homogeneity and thus freedom from phase errors.

For instance, in the event that only one combined measurement data set kMDS1, for example, has been created from all recorded measurement data sets MDS1 . . . MDSN, a minimum homogeneity value Hm can also serve as a quality criterion for measurement data sets MDS1 . . . MDSN to be used when creating calibration data sets KDS without the possibility of comparison with other homogeneity values HW.

If different combined measurement data sets kMDS1 . . . kMDSN+, which completely scan the k-space, are compiled from at least partially different recorded measurement data sets MDS1 . . . MDSN, the determined homogeneity values HW of the phase images PB produced from the different combined complete measurement data sets kMDS1 . . . kMDSN+ can be compared with one another (query Q) and that combined complete measurement data set kMDS1 . . . kMDSN+ whose phase image PB has a preferred homogeneity value HW, for example indicating the greatest homogeneity, used as calibration data set KDS. For example, when considering the HHI as a homogeneity value HW, it is advantageous to create phase images from the combined measurement data sets kMDS1 . . . kMDSN+ completely scanning the k-space as phase jumps in edge regions of different undersampled regions are thus avoided.

Measurement data of measurement data sets MDS1 . . . MDSN (also those measurement data sets MDS1 . . . MDSN from which a combined measurement data set kMDS1 kMDSN+ identified as deviating or insufficient was composed) can be regarded as corrupted, for example by movement of the object to be examined A renewed recording of measurement data of measurement data sets MDS1 . . . MDSN identified as deviating or insufficient can be carried out, e.g. if otherwise no complete calibration data set KDS can be created (as for example, measurement data of k-space positions are still lacking to achieve complete scanning) Such a renewed recording can either be carried out in addition to the measurement data to be recorded for a desired measurement, or, e.g. within the framework of the measurement data sets to be recorded for the desired measurement. For example, in the case of a desired diffusion imaging, measurement data to be recorded again in the context of a further recording of a measurement data set with b=0 or in the case of a desired functional MRI measurement in the context of a next repetition of a recording of a measurement data set to be carried out.

Using the created calibration data set, undersampled recorded measurement data sets, for example, the recorded measurement data sets MDS1 . . . MDSN, if necessary, after a phase correction, can be supplemented to complete measurement data sets MDS1* . . . MDSN* (block 109).

Image data sets BDS can be reconstructed (block 111) from the completed measurement data sets MDS1* . . . MDSN*.

Measurement data sets MDS1 . . . MDSN recorded according to the disclosure permit the creation of calibration data sets which are robust with respect to movements of the object to be examined as a result of their segment-by-segment scanning of the k-space. By determining homogeneity values HW, which allow conclusions to be drawn about a possible corruption of the measurement data by phase errors, the recorded measurement data sets used for the creation of the calibration data sets can be optimally selected to achieve a high image quality in image data sets which have been reconstructed from measurement data sets completed using the calibration data sets.

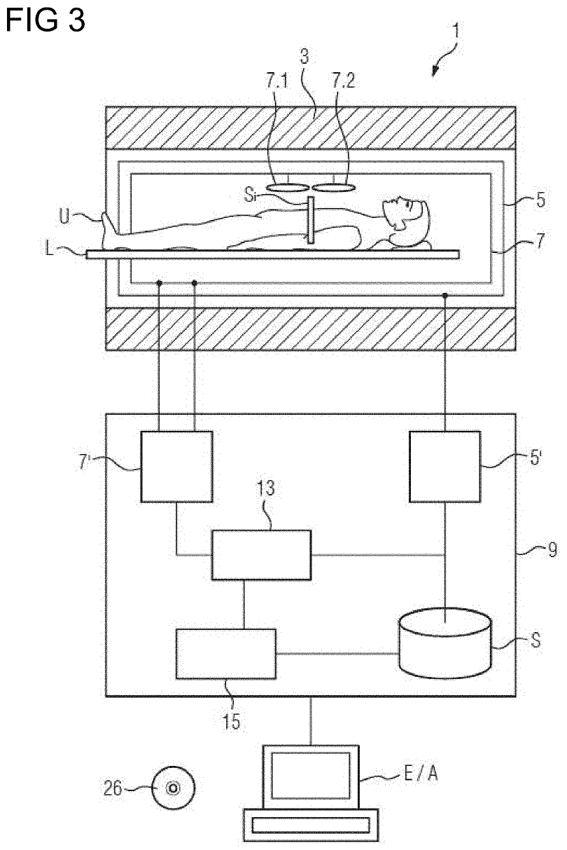

FIG. 3 shows a diagrammatic view of a magnetic resonance system 1 according to the disclosure. This comprises a magnet unit 3 for generating the basic magnetic field, a gradient unit 5 (e.g. gradient generation circuitry) for generating the gradient fields, a radio-frequency (RF) unit 7 (e.g. RF circuitry) for irradiation (i.e. transmission) and for receiving radio-frequency signals, and a control facility 9 (e.g. referred to herein as a control device, control computer, control circuitry), designed to carry out a method according to the disclosure.

FIG. 3 provides only a rough diagrammatic view of these partial units of the magnetic resonance system 1. For example, the RF unit 7 may comprise a plurality of subunits, for example a plurality of coils such as the coils 7.1 and 7.2 shown in a diagrammatic view or more coils, which may be designed either for transmitting radio-frequency signals or for receiving the triggered radio-frequency signals, or both.

For the examination of an object to be examined U, for example a patient or also a phantom, may be introduced into the measurement volume of the magnetic resonance system 1 on a bed L. The layer or the slab Si represents an exemplary target volume of the object to be examined from which echo signals are to be recorded and included as measurement data.

The control device 9 serves to control the magnetic resonance system 1 and can e.g. control the gradient unit 5 by means of a gradient controller 5′, and the radio-frequency unit 7 via a radio-frequency transceiver controller 7′. The radio-frequency unit 7 may comprise a plurality of channels on which signals can be transmitted and/or received.

The radio-frequency unit 7, together with its radio-frequency transceiver controller 7′, is configured to generate and transmit an RF alternating field for manipulating the spins in a region to be manipulated (for example, in layers S to be measured) of the object to be examined U. In this case, the center frequency of the radio-frequency alternating field, also referred to as the B1 field, is generally set as far as possible in such a way that it is close to the resonance frequency of the spins to be manipulated. Deviations from the center frequency by the resonance frequency are referred to as off-resonance. In order to generate the B1 field, controlled currents are applied to the RF coils in the radio-frequency unit 7 by means of the radio-frequency transceiver controller 7′.

Furthermore, the control device 9 comprises a homogeneity determination unit 15 (e.g. homogeneity determination circuitry), with which homogeneity values according to the disclosure can be determined from phase images. The control device 9 may be configured to carry out a method according to the disclosure.

A computing unit 13 (also referred to herein as a computer, controller, or processing circuitry) may be comprised by the control device 9 and is configured to perform all computing operations necessary for the necessary measurements and determinations as discussed above. Intermediate results, and results required for this or determined in the process, can be stored in a storage unit S of the control device 9. The units shown here are not necessarily to be understood as physically separate units, but merely represent a subdivision into sense units which, however, can also be realized for example, in fewer or even in only one physical unit.

Via an input/output device I/O (also referred to herein as an I/O interface or user interface (UI)) of the magnetic resonance system 1, for example, control commands can be sent by a user to the magnetic resonance system and/or results of the control device 9, such as for example, image data, can be displayed.

A method described herein can also be in the form of a computer program product, which comprises a program and implements the method described on a control device 9 when the method is executed on the control device 9. Likewise, an electronically readable data carrier 26 with electronically readable control information stored thereon can be present, which comprises at least one such computer program product as described and is designed in such a way that it carries out the method described when the data carrier 26 is used in a control device 9 of a magnetic resonance system 1.

The various components described herein may be referred to as “devices,” “units” or “facilities.” Such components may be implemented via any suitable combination of hardware and/or software components as applicable and/or known to achieve the intended respective functionality. This may include mechanical and/or electrical components, processors, processing circuitry, or other suitable hardware components. Such components may be configured to operate independently, or configured to execute instructions or computer programs that are stored on a suitable computer readable medium. Regardless of the particular implementation, such devices, units, and facilities, as applicable and relevant, may alternatively be referred to herein as “circuitry,” “processors,” or “processing circuitry,” or alternatively as noted herein.

What is claimed is:

1. A method for generating calibration data for completing undersampled measurement data of an object to be examined via a magnetic resonance system, comprising:
recording N measurement data sets using an acquisition scheme that subsamples k-space with an acceleration factor R, with N being is greater than or equal to R, and the N measurement data sets together sampling the k-space completely;
generating phase images from the N recorded measurement data sets;
determining a homogeneity value of the phase images; and
generating a complete calibration data set based upon the N recorded measurement data sets and the homogeneity value.

2. The method as claimed in claim 1, wherein each phase image from among the phase images is generated from each respective one of the N recorded measurement data sets.

3. The method as claimed in claim 1, wherein a number M of recorded measurement data sets are combined to form a combined measurement data set, and further comprising:
determining a phase image of the combined measurement data set,
wherein 2≤M≤R.

4. The method as claimed in claim 3, wherein the M recorded measurement data sets of the combined measurement data set completely scan k-space.

5. The method as claimed in claim 3, further comprising:
generating a combined measurement data set comprising two recorded measurement data sets that are averaged, the two recorded measurement data sets scanning the same k-space positions.

6. The method as claimed in claim 1, further comprising:
comparing homogeneity values of respective phase images;
when a deviation of a homogeneity value of a phase image determined from a first recorded measurement data set and homogeneity values of other determined phase images of measurement data sets exceeds a first predetermined threshold value, the first recorded measurement data set is not used in the generation of the calibration data set; and
when a deviation of a homogeneity value of a phase image determined from a first combined measurement data set and homogeneity values of other determined phase images of measurement data sets combined from (i) other recorded measurement data sets, or (ii) from other partially different recorded measurement data sets, exceeds a second predetermined threshold value, the first combined measurement data set is not used in the generation of the calibration data set.

7. The method as claimed in claim 1, further comprising:
comparing homogeneity values of respective phase images with a predetermined minimum homogeneity value;
when the homogeneity value of a respective phase image determined from (i) a second recorded measurement data set, or (ii) from a second combined measurement data set, does not meet the minimum homogeneity value, the second recorded measurement data set or the second combined measurement data set identified that does not meet the minimum homogeneity value is not used in the generation of the calibration data set.

8. The method as claimed in claim 4, wherein different combined measurement data sets are composed of at least partially different recorded measurement data sets, and further comprising:
comparing the determined homogeneity values of the respective phase images generated from the different combined measurement data sets; and
using, as a calibration data set, one of the different combined measurement data sets having a phase image corresponding to a predetermined homogeneity value.

9. The method as claimed in claim 6, wherein a new recording of measurement data sets identified as having respective homogeneity values deviating from the first predetermined threshold value or the second predetermined threshold value is carried out when a complete calibration data set cannot be created.

10. The method as claimed in claim 1, wherein the determination of a homogeneity value comprises:
calculating absolute values of phase gradients, a determination of auto-correlation values of the phase images in one dimension, and/or a determination of Haralick's homogeneity index.

11. The method as claimed in claim 1, further comprising:
performing a phase correction of the recorded measurement data sets to generate phase-corrected measurement data sets; and
generating the phase images from the phase-corrected measurement data sets.

12. The method as claimed in claim 1, wherein the recorded measurement data sets comprise measurement data sets to be recorded repeatedly as part of a diffusion measurement with a diffusion value b=0.

13. The method as claimed in claim 1, wherein the recorded measurement data sets comprise measurement data sets to be recorded repeatedly as part of a functional magnetic resonance measurement.

14. The method as claimed in claim 1, wherein the recorded measurement data sets are acquired as part of dummy recordings.

15. The method as claimed in claim 1, wherein the recorded measurement data sets comprise reference data measurements to be performed repeatedly as part of dynamic field corrections or as dynamic reference measurements.

16. A magnetic resonance system, comprising:
a magnet unit;
gradient generation circuitry;
radio-frequency (RF) circuitry; and
control circuitry configured to generate calibration data for completing undersampled measurement data of an object to be examined via the magnetic resonance system by:
recording N measurement data sets using an acquisition scheme that subsamples k-space with an acceleration factor R, with N being is greater than or equal to R, and the N measurement data sets together sampling the k-space completely;
generating phase images from the N recorded measurement data sets;
determining a homogeneity value of the phase images; and
generating a complete calibration data set based upon the N recorded measurement data sets and the homogeneity value.

17. A non-transitory computer readable medium having instructions stored thereon that, when executed by control circuitry of a magnetic resonance system, cause the magnetic resonance system to generate calibration data for completing undersampled measurement data of an object to be examined via the magnetic resonance system by:
recording N measurement data sets using an acquisition scheme that subsamples k-space with an acceleration factor R, with N being is greater than or equal to R, and the N measurement data sets together sampling the k-space completely;
generating phase images from the N recorded measurement data sets;
determining a homogeneity value of the phase images; and
generating a complete calibration data set based upon the N recorded measurement data sets and the homogeneity value
